(19) United States
(12) Patent Application Publication
(10) Pub. No.: US 2025/0299311 A1
(43) Pub. Date: Sep. 25, 2025

(54) METHOD OF MEASURING THICKNESS OF LIGHT EMITTING MEMBER AND METHOD OF MANUFACTURING DISPLAY PANEL USING THE SAME

(71) Applicant: Samsung Display Co., LTD., Yongin-si (KR)

(72) Inventor: Seung Hwa JEONG, Yongin-si (KR)

(73) Assignee: Samsung Display Co., LTD., Yongin-si (KR)

(21) Appl. No.: 18/966,825

(22) Filed: Dec. 3, 2024

(30) Foreign Application Priority Data
Mar. 25, 2024 (KR) 10-2024-0040327

(51) Int. Cl. G06T 7/00; G06T 7/60; H10K 59/12; H10K 71/13

(52) U.S. Cl. CPC G06T 7/0004; G06T 7/60; H10K 59/1201; H10K 71/135; G06T 2200/04

(57) ABSTRACT

There is provided a method of manufacturing a light emitting member. The method includes forming a first electrode on a substrate, forming the light emitting member on the first electrode, generating a two-dimensional image by photographing the light emitting member, converting the two-dimensional image into a three-dimensional image, using an artificial intelligence device, and measuring a thickness of the light emitting member, based on the three-dimensional image.

### CROSS-REFERENCE TO RELATED APPLICATION(S)

This application claims priority to and benefits of Korean patent application No. 10-2024-0040327 under 35 U.S.C. § 119 filed on Mar. 25, 2024, in the Korean Intellectual Property Office, the entire contents of which are incorporated herein by reference.

### BACKGROUND

### 1. Technical Field

Embodiments relate to a method of measuring a thickness of a light emitting member and a method of manufacturing a display panel including the light emitting member, and more particularly, to a method of measuring a thickness of a light emitting member using an artificial intelligence device and a method of manufacturing a display panel including the light emitting member.

### 2. Description of the Related Art

With the development of information technologies, the importance of a display device which is a connection medium between a user and information increases. Accordingly, display devices such as a liquid crystal display device, an organic light emitting display device, and inorganic light emitting display device are increasingly used.

A display device includes a display device including sub-pixels to display an image, each of the sub-pixels includes a light emitting element, and the light emitting element includes a light emitting member generating light. The thickness uniformity of the light emitting element may vary according to an environment (or condition) in which the light emitting member is formed (hereinafter, referred to as a ‘formation environment’ or ‘formation condition’). In case that the thickness of the light emitting member is not uniform, the performance of the light emitting element may be deteriorated.

### SUMMARY

Embodiments provide a method of measuring a thickness of a light emitting member, in which the thickness of the light emitting member is measured through a two-dimensional image.

Embodiments also provide a method of manufacturing a display panel, using the method of measuring the thickness of the light emitting member.

However, embodiments are not limited to those set forth herein. The above and other embodiments will become more apparent to one of ordinary skill in the art to which the disclosure pertains by referencing the detailed description of the disclosure given below.

In accordance with an aspect of the disclosure, there is provided a method of manufacturing a light emitting member, the method including: forming a first electrode on a substrate; forming the light emitting member on the first electrode; generating a two-dimensional image by photographing the light emitting member; converting the two-dimensional image into a three-dimensional image, using an artificial intelligence device; and measuring the thickness of the light emitting member, based on the three-dimensional image.

The light emitting member may be formed by an inkjet printing process.

The light emitting member may be configured with a plurality of layers.

A thickness of each of the plurality of layers may be measured based on the three-dimensional image.

The artificial intelligence device may operate based on an artificial intelligence model which converts an arbitrary two-dimensional image into a three-dimensional image corresponding to the arbitrary two-dimensional image, and the artificial intelligence model is stored in a non-transitory computer-readable medium with instructions stored thereon, is obtained through an iterative optimization process by minimizing errors between predicted thicknesses and actual thicknesses.

The light emitting member may be photographed after the plurality of layers are all formed.

The forming of the light emitting member may include: providing a first ink including a first layer among the plurality of layers; drying the first ink; providing, on the first ink, a second ink including a second layer among the plurality of layers; and drying the second ink.

The forming of the light emitting member may further include: baking the dried first ink; and baking the dried second ink.

An upper surface of the light emitting member may be photographed.

The light emitting member may include: a hole injection layer; a hole transporting layer; a light emitting layer; an electron transporting layer; and an electron injection layer.

In accordance with another aspect of the disclosure, there is provided a method of manufacturing a display panel including a light emitting member, the method including: measuring a thickness of the light emitting member according to a plurality of conditions; setting any one of the plurality of conditions as a formation condition of the light emitting member, based on the measured thickness; and forming the light emitting member in the formation condition, wherein the measuring of the thickness of the light emitting member includes: forming a first electrode on a substrate; forming the light emitting member on the first electrode; generating a two-dimensional image by photographing the light emitting member; converting the two-dimensional image into a three-dimensional image, using an artificial intelligence device; and measuring the thickness of the light emitting member, based on the three-dimensional image.

The light emitting member may be formed by an inkjet printing process.

The light emitting member may be configured with a plurality of layers.

A thickness of each of the plurality of layers may be measured based on the three-dimensional image.

The artificial intelligence device may operate based on an artificial model which converts an arbitrary two-dimensional image into a three-dimensional image corresponding to the arbitrary two-dimensional image, and the artificial intelligence model is stored in a non-transitory computer-readable medium with instructions stored thereon, is obtained through an iterative optimization process by minimizing errors between predicted thicknesses and actual thicknesses.

The light emitting member may be photographed after the plurality of layers are formed.

The forming of the light emitting member may include: providing a first ink including a first layer among the plurality of layers; drying the first ink; providing, on the first ink, a second ink including a second layer among the plurality of layers; and drying the second ink.

The forming of the light emitting member may further include: baking the dried first ink; and baking the dried second ink.

An upper surface of the light emitting member may be photographed.

The light emitting member may include: a hole injection layer; a hole transporting layer; a light emitting layer; an electron transporting layer; and an electron injection layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display panel in accordance with embodiments.

FIG. 2 is a schematic plan view illustrating a pixel included in the display panel.

FIG. 3 is a schematic view illustrating an example of a light emitting element of the display panel shown in FIG. 1.

FIG. 4 is a flowchart illustrating a method of manufacturing the display panel in accordance with embodiments.

FIG. 5 is a flowchart illustrating a step S100 shown in FIG. 4.

FIGS. 6 to 11 are schematic views illustrating the step S100 shown in FIG. 4.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction D1, the axis of the second direction D2, and the axis of the third direction D3 are not limited to three axes of a rectangular coordinate system, such as the X, Y, and Z-axes, and may be interpreted in a broader sense. For example, the axis of the first direction D1, the axis of the second direction D2, and the axis of the third direction D3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described in detail with reference to the accompanying drawings.

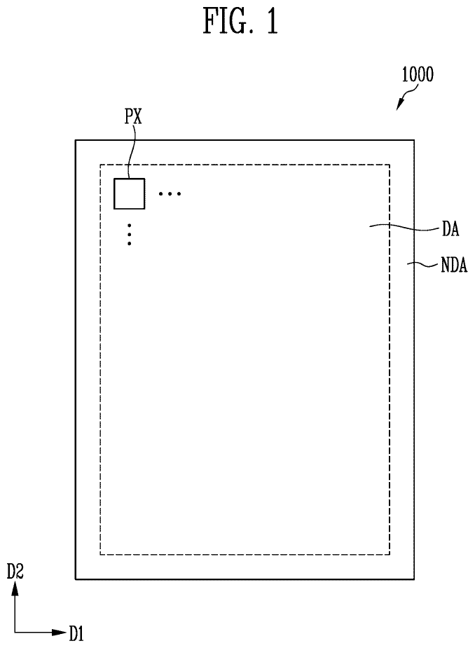

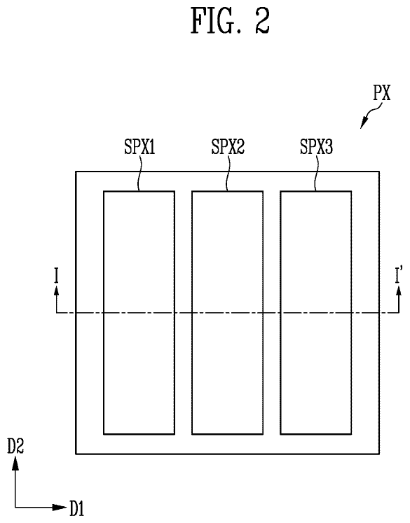

FIG. 1 is a schematic plan view illustrating a display panel 1000 in accordance with embodiments. FIG. 2 is a schematic plan view illustrating a pixel PX included in the display panel 1000.

Referring to FIGS. 1 and 2, the display panel 1000 may include a display area DA and a non-display area NDA. An image may be displayed in the display area DA. The non-display area NDA may be positioned at the periphery of the display area DA.

The display panel 1000 may include pixels PX disposed in the display area DA. For example, the pixels PX may be disposed in a matrix form along a first direction D1 and a second direction D2 intersecting the first direction D1.

Each of the pixels PX may include sub-pixels emitting lights of different colors. In an embodiment, each of the pixels PX may include first to third sub-pixels SPX1, SPX2, and SPX3 emitting lights of different colors. For example, the first sub-pixel SPX1 may emit red light, the second sub-pixel SPX2 may emit green light, and the third sub-pixel SPX3 may emit blue light. However, embodiments are not limited thereto.

Each of the first to third sub-pixels SPX1, SPX2, and SPX3 may include a transistor and a light emitting element. The transistor may generate a driving current, and provide the generated driving current to the light emitting element. The light emitting element may emit light, based on the driving current. For example, the light emitting element may include an organic light emitting diode, an inorganic light emitting diode, a quantum dot light emitting diode, or the like.

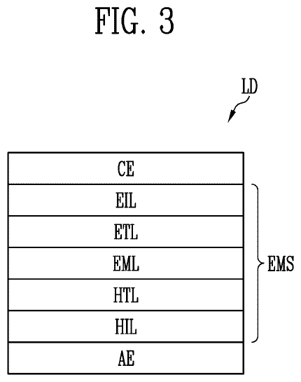

FIG. 3 is a schematic view illustrating an example of the light emitting element of the display panel shown in FIG. 1.

Referring to FIG. 3, a light emitting element LD may include a first electrode AE (i.e., an anode electrode), a light emitting member EMS, and a second electrode CE (i.e., a cathode electrode). The light emitting member (or light emitting member) EMS may include a plurality layers.

The light emitting member EMS may include a hole injection layer HIL and a hole transporting layer HTL. The hole injection layer HIL may be disposed on the first electrode AE, and the hole transporting layer HTL may be disposed on the hole injection layer HIL. The hole injection layer HIL and the hole transporting layer HTL may allow holes injected from the first electrode AE to be readily transported therethrough. The hole injection layer HIL may include tris(4-carbazoyl-9-ylphenyl)amine (TCTA), 4,4′,4″-Tris[(3-methylphenyl)phenylamino]triphenylamine (m-MTDATA), IDE406 (Idemitsu Kosan Co., Ltd), and the like, which are CuPc or starburst-type amines. The hole transporting layer HTL may include N,N′-Bis(3-methylphenyl)-N,N′-diphenylbenzidine (TPD) or α-TPD, or the like.

The light emitting member EMS may include a light emitting layer EML. The light emitting layer EML may be disposed on the hole transport layer HTL. The light emitting layer EML may include at least one of an organic light emitting material and a quantum dot.

In an embodiment, the organic light emitting material may include a low molecular organic compound or a high molecular organic compound. Examples of the low molecular organic compound may be copper phthalocyanine, diphenylbenzidine (N,N′-diphenylbenzidine), trihydroxyquinoline aluminum (tris-(8-hydroxyquinoline)aluminum), and the like. Examples of the high molecular organic compound may be poly ethylenedioxythiophene (poly(3,4-ethylenedioxythiophene), polyaniline, polyphenylenevinylene, polyfluorene, and the like. These may be used alone or in combination thereof.

In an embodiment, the quantum dot may include a core including a group II-VI compound, a group III-V compound, a group IV-VI compound, a group IV element, a group IV compound, and a combination thereof. In an embodiment, the quantum dot may have a core-shell structure including a core and a shell surrounding the core. The shell may prevent chemical denaturation of the core, thereby serving (or acting) as a protective layer for maintaining semiconductor characteristics and a charging layer for imparting electrophoretic characteristics to the quantum dot.

The light emitting member EMS may include an electron transporting layer ETL and an electron injection layer EIL. The electron transporting layer ETL may be disposed on the light emitting layer EML, and the electron injection layer EIL may be disposed on the electron transporting layer ETL. The second electrode CE may be disposed on the electron injection layer EIL. The electron injection layer EIL and the electron transporting layer ETL may allow electrons injected from the second electrode CE to be readily transported therethrough. The electron transporting layer ETL may include Alq₃, pyrrolobenzodiazepine (PBD), TNF, butanamide (BMD), BND, and the like. The electron injection layer EIL may include LiF, LiQ, NaCL, CsF, Li₂O, BaO, and the like.

The first electrode AE may be in contact with circuit elements including the above-described transistor. Holes injected from the first electrode AE and electrons injected from the second electrode CE may be transported into the light emitting layer EML of the light emitting member EMS to form excitons, and light may be generated in case that the excitons are changed from an excited state to a ground state. A luminance of the light may be determined according to an amount of current flowing through the light emitting layer EML. A wavelength band of the generated light may be determined according to a configuration of the light emitting layer EML.

The light emitting member EMS may be formed by an inkjet printing process. For example, the hole injection layer HIL, the hole transporting layer HTL, the light emitting layer EML, the electron transporting layer ETL, and the electron injection layer EIL may be sequentially formed by the inkjet printing process.

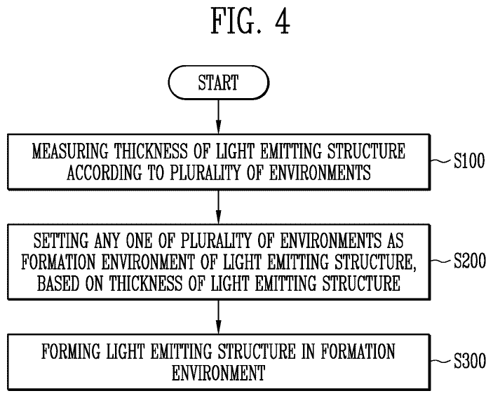

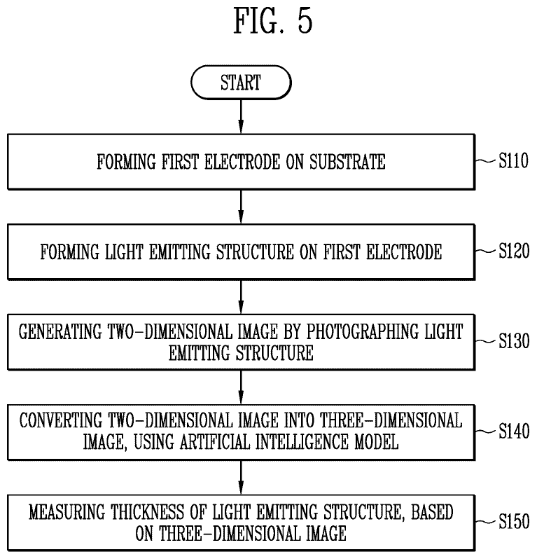

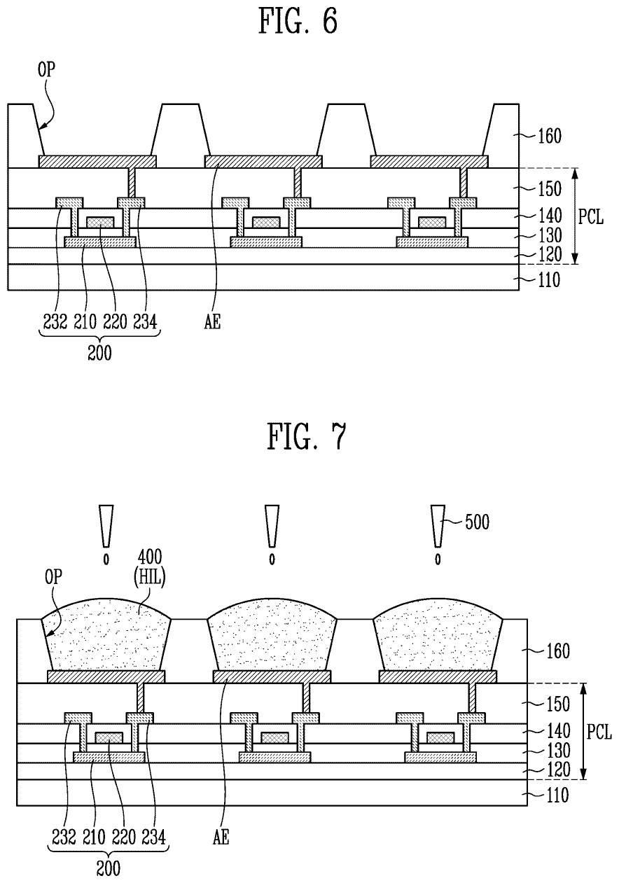

FIG. 4 is a flowchart illustrating a method of manufacturing the display panel in accordance with embodiments. FIG. 5 is a flowchart illustrating a step S100 shown in FIG. 4. FIGS. 6 to 11 are schematic views illustrating the step S100 shown in FIG. 4.

For descriptive convenience, FIGS. 7 to 10 describe a process of forming the hole injection layer HIL, and the other layers of the light emitting member EMS may be substantially formed by the same process as the hole injection layer HIL.

Referring to FIG. 4, the method of manufacturing the display panel may include a step S100 of measuring a thickness of the light emitting member EMS according to environments (or conditions), a step S200 of setting any one of the plurality of environments (or conditions) as a formation environment (or formation condition) of the light emitting member, based on the thickness of the light emitting member, and a step S300 of forming the light emitting member in the formation environment (or formation condition).

In case that the thickness of the light emitting member is not uniform, the performance of the light emitting element may be deteriorated. For example, the thickness uniformity of the light emitting member may vary according to the formation environment (or formation condition) of the light emitting member. Therefore, in the method of manufacturing the display panel, thickness uniformity of the light emitting member according to each of the environments (or conditions) may be measured, an environment (or condition) in which the thickness of the light emitting member is most uniform may be determined as the formation environment (or formation condition), and the light emitting element may be formed in the formation environment (or formation condition). However, in the disclosure, the environment (or condition) in which the thickness of the light emitting member is most uniform is not necessarily to be determined as the formation environment (or formation condition), but the measured thickness of the light emitting member may be used as one factor for determining the formation environment (or formation condition).

An environment (or condition) may include various factors in a process of forming the light emitting member, such as a viscosity of an ink, a surface tension of the ink, a boiling point of the ink, a temperature in a drying process, and a pressure in the drying process. Embodiments are not limited to the factors included in the environment (or condition).

Referring to FIG. 5, the step 100 of measuring the thickness of the light emitting member may include a step S110 of forming a first electrode on a substrate, a step S120 of forming the light emitting member on the first electrode, a step S130 of generating a two-dimensional image by photographing the light emitting member, a step S140 of converting the two-dimensional image into a three-dimensional image, using an artificial intelligence device, and a step S150 of measuring a thickness of the light emitting member, based on the three-dimensional image.

Hereinafter, this will be described in detail.

Referring to FIG. 6, a transistor 200 may be formed on a substrate 110.

For example, a buffer layer 120 may be formed on the substrate 110. After that, an active layer 210 may be formed on the buffer layer 120. The active layer 210 may be formed using an oxide semiconductor, a silicon semiconductor, an organic semiconductor, or the like.

A first insulating layer 130 may be formed on the buffer layer 120. The first insulating layer 130 may cover the active layer 210 on the buffer layer 120. The first insulating layer 130 may be formed using an inorganic insulating material.

A gate electrode 220 may be formed on the first insulating layer 130. The gate electrode 220 may be formed using a conductive material.

A second insulating layer 140 may be formed on the first insulating layer 130. The second insulating layer 140 may cover the gate electrode 220 on the first insulating layer 130. The second insulating layer 140 may be formed using an inorganic insulating material.

Contact holes may be formed in the first insulating layer 130 and the second insulating layer 140 to respectively overlap a source region and a drain region. For example, a source electrode 232 and a drain electrode 234 may be formed on the second insulating layer 140 to respectively overlap the contact holes. Each of the source electrode 232 and the drain electrode 234 may be formed using a conductive material. The source electrode 232 and the drain electrode 234 may be connected to the source region and the drain region through the contact holes, respectively. Accordingly, the transistor 200, which includes the active layer 210, the gate electrode 220, the source electrode 232, and the drain electrode 234, may be formed on the substrate 110.

A third insulating layer 150 covering the transistor 200 may be formed on the second insulating layer 140. The third insulating layer 150 may cover the source electrode 232 and the drain electrode 234 on the second insulating layer 140. The third insulating layer 150 may be formed using an organic insulating material.

Contact holes may be formed in the third insulating layer 150 to overlap the drain electrode 234. For example, a first electrode AE may be formed on the third insulating layer 150 to overlap each of the contact holes. The first electrode AE may be formed using a conductive material.

A pixel defining layer 160 may be formed on the third insulating layer 150. The pixel defining layer 160 may form an opening OP. The opening OP may be formed to expose a portion or the whole of the first electrode AE. Accordingly, a portion of the first electrode AE may be exposed to the outside.

Referring to FIGS. 7 to 9, the light emitting member EMS (see FIG. 3) may be formed by an inkjet printing process.

For example, as shown in FIG. 7, an inkjet printing apparatus may discharge an ink 400 including a hole injection layer HIL into the opening OP through a nozzle 500. The ink 400 including the hole injection layer HIL means an ink including materials of the hole injection layer HIL.

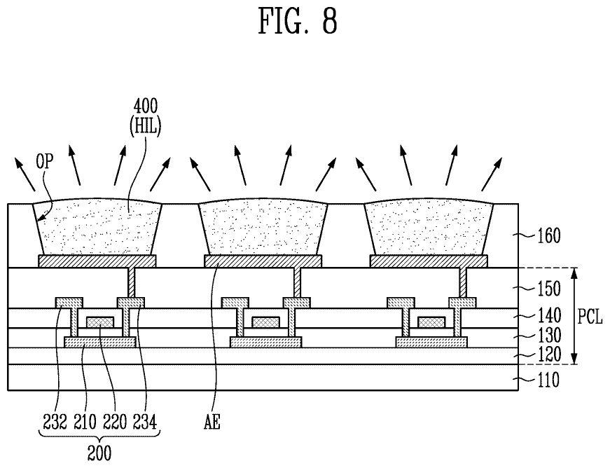

For example, as shown in FIG. 8, the ink 400 may be dried. While the ink 400 is dried, a solvent in the ink 400 may be evaporated, and only the materials of the hole injection layer HIL included in the ink 400 may remain. In an embodiment, drying may be performed in a specific drying environment (or drying condition). In an embodiment, the drying may be performed in a chamber forming the drying environment (or drying condition). The drying environment (or drying condition) means a temperature, a pressure, and the like.

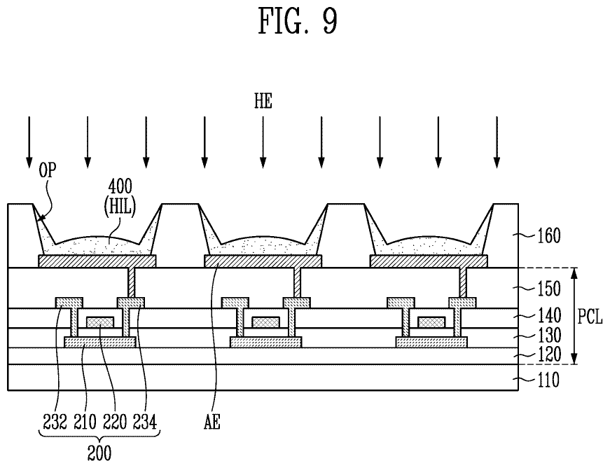

For example, as shown in FIG. 9, the dried ink 400 may be baked. For example, heat HE may be applied to the dried ink 400. Accordingly, as the dried ink 400 is cured, the hole injection layer HIL may be formed.

As the processes shown in FIGS. 7 to 9 are repeated after the hole injection layer HIL is formed, a hole transporting layer HTL (see FIG. 3), a light emitting layer EML (see FIG. 3), an electron transporting layer ETL (see FIG. 3), and an electron injection layer EIL (see FIG. 3) may be sequentially formed.

As shown in FIG. 9, the hole injection layer HIL may have a curved shape according to the drying environment (or drying condition). In case that the hole injection layer HIL does not have a uniform thickness, the performance of the light emitting element LD (see FIG. 3) may be deteriorated. This is the same as the other layers of the light emitting member EMS except the hole injection layer HIL.

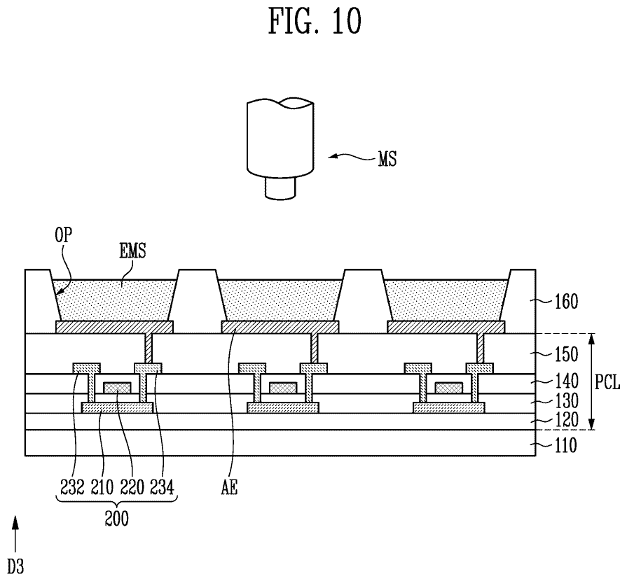

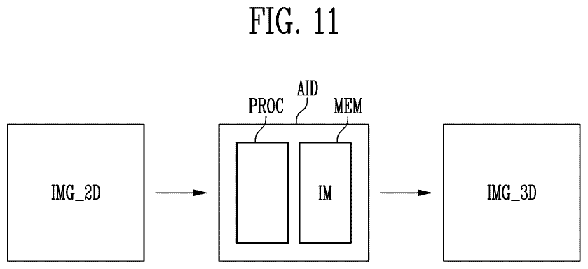

Referring to FIGS. 10 and 11, the light emitting member EMS may be photographed after a plurality of layers are all formed. The light emitting member EMS may be photographed by a photographing apparatus MS, and a two-dimensional image IMG_2D may be generated. For example, the photographing apparatus MS may photograph a top surface (or upper surface) of the light emitting member EMS (i.e., photographing in a third direction D3). For example, the photographing apparatus MS may be a microscope. However, embodiments are not limited to the kind of photographing apparatus.

The two-dimensional image IMG_2D may be converted into a three-dimensional image IMG_3D, using an artificial intelligence device AID, which operates based on an artificial intelligence model (or artificial intelligence program) IM. A thickness of the light emitting member EMS may be measured based on the three-dimensional image IMG_3D.

For example, the artificial intelligence device AID may include a processor PROC and a memory MEM. The processor PROC may include a central processing unit (CPU), an application processors (AP), a communication processor (CP), an image signal processor (ISP), a neural network processing device (NPU), and a graphic processing unit (GPU). For example, the memory MEM may include a volatile memory and a non-volatile memory. The memory MEM may store the artificial intelligence model (or artificial intelligence program) IM. The artificial intelligence device AID may operate based on the artificial intelligence model (or artificial intelligence program) IM which converts an arbitrary two-dimensional image into a three-dimensional image corresponding to the arbitrary two-dimensional image. In an embodiment, the existing model (or existing program) which converts a two-dimensional image into a corresponding three-dimensional image may be used as the artificial intelligence device AID. The artificial intelligence device AID may perform data processing on the two-dimensional image, which is obtained by the photographing apparatus MS, to generate the three-dimensional image based on the artificial intelligence model (or artificial intelligence program) IM. For example, the artificial intelligence model (or artificial intelligence program) IM may be stored in non-transitory computer-readable medium (e.g., MEM) with instructions stored thereon. In an embodiment, the artificial intelligence model (or artificial intelligence program) IM may be a model (or program) learned using data obtained by actually measuring the thickness of the light emitting member EMS. For example, the artificial intelligence model (or artificial intelligence program) IM may learn and be trained to predict the thicknesses of the light emitting member EMS based on the measured two-dimensional image through an iterative optimization process that minimizes the errors between the predicted thicknesses and the actual thicknesses. Thus, the thicknesses of the light emitting member EMS may be obtained without using a three-dimensional measurement tools, thereby simplifying the manufacturing process and reducing the manufacturing cost.

A thickness of each of the plurality of layers of the light emitting member EMS may be measured based on the three-dimensional image IMG_3D. As the light emitting member EMS is formed by the inkjet printing process, the plurality of layers except the electron injection layer EIL (see FIG. 3) may be viewed at an edge portion of the light emitting member EMS in case that the top surface (or upper surface) of the light emitting member EMS is viewed (i.e., when viewed in the third direction D3). For example, when the top surface (or upper surface) of the light emitting member EMS is viewed, the plurality of layers except the electron injection layer EIL (see FIG. 3) may also be viewed. Therefore, the three-dimensional image IMG_3D generated based on the two-dimensional image IMG_2D obtained by photographing the top surface (or upper surface) of the light emitting member EMS may represent the thickness of each of the plurality of layers.

Embodiments may be applied to display devices and electronic devices including the display devices. For example, embodiments may be applied to digital TVs, 3D TVs, mobile phones, smart phones, tablet computers, VR devices, PCs, home appliances, notebook computers, PDAs, PMPs, digital cameras, music players, portable game consoles, navigation systems, and the like.

In accordance with the disclosure, the method of measuring the thickness of the light emitting member EMS uses an artificial intelligence device AID, which operates based on an artificial intelligence model IM, so that the thickness of the light emitting member EMS may be measured using only a two-dimensional image. Accordingly, processes for measuring the thickness of the light emitting member EMS may be simplified.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A method of manufacturing a light emitting member, the method comprising:
forming a first electrode on a substrate;
forming the light emitting member on the first electrode;
generating a two-dimensional image by photographing the light emitting member;
converting the two-dimensional image into a three-dimensional image, using an artificial intelligence device; and
measuring a thickness of the light emitting member, based on the three-dimensional image.

2. The method of claim 1, wherein the light emitting member is formed by an inkjet printing process.

3. The method of claim 1, wherein the light emitting member includes a plurality of layers.

4. The method of claim 3, wherein a thickness of each of the plurality of layers is measured based on the three-dimensional image.

5. The method of claim 4, wherein
the artificial intelligence device operates based on an artificial intelligence model which converts an arbitrary two-dimensional image into a three-dimensional image corresponding to the arbitrary two-dimensional image, and
the artificial intelligence model, which is stored in a non-transitory computer-readable medium with instructions stored thereon, is obtained through an iterative optimization process by minimizing errors between predicted thicknesses and actual thicknesses.

6. The method of claim 3, wherein the light emitting member is photographed after the plurality of layers are formed.

7. The method of claim 3, wherein the forming of the light emitting member includes:
providing a first ink including a first layer among the plurality of layers;
drying the first ink;
providing, on the first ink, a second ink including a second layer among the plurality of layers; and
drying the second ink.

8. The method of claim 7, wherein the forming of the light emitting member further includes:
baking the dried first ink; and
baking the dried second ink.

9. The method of claim 1, wherein an upper surface of the light emitting member is photographed.

10. The method of claim 1, wherein the light emitting member includes:
a hole injection layer;
a hole transporting layer;
a light emitting layer;
an electron transporting layer; and
an electron injection layer.

11. A method of manufacturing a display panel including a light emitting member, the method comprising:
measuring a thickness of the light emitting member according to a plurality of conditions;
setting any one of the plurality of conditions as a formation condition of the light emitting member, based on the measured thickness; and
forming the light emitting member in the formation condition,
wherein the measuring of the thickness of the light emitting member includes:
forming a first electrode on a substrate;
forming the light emitting member on the first electrode;
generating a two-dimensional image by photographing the light emitting member;
converting the two-dimensional image into a three-dimensional image, using an artificial intelligence device; and
measuring the thickness of the light emitting member, based on the three-dimensional image.

12. The method of claim 11, wherein the light emitting member is formed by an inkjet printing process.

13. The method of claim 11, wherein the light emitting member includes a plurality of layers.

14. The method of claim 13, wherein a thickness of each of the plurality of layers is measured based on the three-dimensional image.

15. The method of claim 14, wherein
the artificial intelligence device operates based on an artificial intelligence model which converts an arbitrary two-dimensional image into a three-dimensional image corresponding to the arbitrary two-dimensional image, and
the artificial intelligence model, which is stored in a non-transitory computer-readable medium with instructions stored thereon, is obtained through an iterative optimization process that minimizes errors between predicted thicknesses and actual thicknesses.

16. The method of claim 13, wherein the light emitting member is photographed after the plurality of layers are formed.

17. The method of claim 13, wherein the forming of the light emitting member includes:
providing a first ink including a first layer among the plurality of layers;
drying the first ink;
providing, on the first ink, a second ink including a second layer among the plurality of layers; and
drying the second ink.

18. The method of claim 17, wherein the forming of the light emitting member further includes:
baking the dried first ink; and
baking the dried second ink.

19. The method of claim 11, wherein an upper surface of the light emitting member is photographed.

20. The method of claim 11, wherein the light emitting member includes:
a hole injection layer;
a hole transporting layer;
a light emitting layer;
an electron transporting layer; and
an electron injection layer.
